(19) United States
(12) Patent Application Publication
(10) Pub. No.: US 2013/0098432 A1
(43) Pub. Date: Apr. 25, 2013

(54) SOLAR CELLS

(71) Applicants: JungWook LIM, Daejeon (KR); Sun Jin Yun, Daejeon (KR)

(72) Inventors: JungWook LIM, Daejeon (KR); Sun Jin Yun, Daejeon (KR)

(73) Assignee: ELECTRONICS AND TELECOMMUNICATIONS RESEARCH INSTITUTE, Daejeon (KR)

(21) Appl. No.: 13/614,077

(22) Filed: Sep. 13, 2012

(30) Foreign Application Priority Data
Oct. 19, 2011 (KR) 10-2011-0106866

(51) Int. Cl. H01L 31/075

(52) U.S. Cl. 136/255

(57) ABSTRACT

Solar cells are provided. The solar cell may include a substrate, a first electrode on the substrate, a first light absorption layer disposed on the first electrode and including silicon containing oxygen, a second light absorption layer disposed on the first light absorption layer and including silicon containing germanium, and a second electrode on the second light absorption layer. The first light absorption layer may include a plurality of semiconductor layers which have oxygen-content ratios different from each other, respectively. The second light absorption layer may include a plurality of semiconductor layers which have germanium-content ratios different from each other, respectively.

### CROSS-REFERENCE TO RELATED APPLICATIONS

This U.S. non-provisional patent application claims priority under 35 U.S.C. §119 to Korean Patent Application No. 10-2011-0106866, filed on Oct. 19, 2011, the entirety of which is incorporated by reference herein.

### BACKGROUND

The inventive concept relates to solar cells and, more particularly, to thin film silicon solar cells having a tandem structure.

Solar cells may be photoelectric conversion systems converting light energy outputted from the sun into electric energy. The solar cells may generate an electric power by using an infinite sunlight source and pollution may not occur during generation of the electric power. Thus, the solar cells are be highlighted as a new environment-friendly energy source. The solar cells can be categorized as any one of crystalline silicon solar cells using a wafer used in a semiconductor device and thin film solar cells using a substrate such as a glass. The thin film solar cells may classified into amorphous or crystalline silicon thin film solar cells, copper-indium-gallium-selenium (CIGS) thin film solar cells, CdTe thin film solar cells, and dye-sensitized solar cells according to materials used in the thin film solar cells.

The silicon thin film solar cells may be easily to have a wide area as compared with the CIGS or CdTe thin film solar cells. However, the silicon thin film solar cells may have a low light absorption rate. For increasing the light absorption rate of the silicon thin film solar cells, defects of a silicon layer corresponding to a light absorption layer may become reduced, other materials may be added into the silicon layer, interface defects consuming carriers of electron-hole may become reduced, or a tandem structure may be used in the solar cells.

Single-crystalline silicon may have an energy band gap of about 1.1 eV, GaAs may have an energy band gap of about 1.43 eV, CdTe may have an energy band gap of about 1.49 eV, and an amorphous silicon thin film may have an energy band gap within a range of about 1.4 eV to about 1.9 eV. The sunlight may have a broadband wavelength spectrum. Thus, if the light absorption layer of the solar cells is formed of one of the above materials, the solar cells may absorb light of predetermined wavelength band. However, since the tandem solar cell having the tandem structure may include stacked layers of which light absorption bands are different from each other, the tandem solar cell may absorb broadband light.

### SUMMARY

Embodiments of the inventive concept may provide solar cells capable of increasing light absorption rate by suitably controlling energy band gaps of light absorption layers of a tandem structure.

Embodiments of the inventive concept may also provide solar cells capable of increasing light absorption rate by effectively scattering sunlight using a selective transmitting layer.

According to embodiments of the inventive concepts, a solar cell may include: a substrate; a first electrode on the substrate; a first light absorption layer on the first electrode, the first light absorption layer including silicon containing oxygen; a second light absorption layer on the first light absorption layer, the second light absorption layer including silicon containing germanium; and a second electrode on the second light absorption layer. The first light absorption layer may include a plurality of semiconductor layers which have oxygen-content ratios different from each other, respectively. The second light absorption layer may include a plurality of semiconductor layers which have germanium-content ratios different from each other, respectively.

In some embodiments, the first light absorption layer may include: a first p-type semiconductor layer on the first electrode; a first i-type semiconductor layer on the first p-type semiconductor layer, the first i-type semiconductor layer having an oxygen-content ratio lower than an oxygen-content ratio of the first p-type semiconductor layer; and a first n-type semiconductor layer on the first i-type semiconductor layer, the first n-type semiconductor layer having an oxygen-content ratio lower than an oxygen-content ratio of the first i-type semiconductor layer.

In other embodiments, the oxygen-content ratio of the first i-type semiconductor layer may be gradually reduced from the first p-type semiconductor layer toward the first n-type semiconductor layer.

In still other embodiments, the second light absorption layer may include: a second p-type semiconductor layer on the first n-type semiconductor layer; a second i-type semiconductor layer on the second p-type semiconductor layer, the second i-type semiconductor layer having a germanium-content ratio higher than a germanium-content ratio of the second p-type semiconductor layer; and a second n-type semiconductor layer on the second i-type semiconductor layer, the second n-type semiconductor layer having a germanium-content ratio higher than a germanium-content ratio of the second i-type semiconductor layer.

In yet other embodiments, the germanium-content ratio of the second i-type semiconductor layer may be gradually increased from the second p-type semiconductor layer toward the second n-type semiconductor layer.

In yet still other embodiments, a maximum value of the germanium-content ratio of the second i-type semiconductor layer may be about 20% or less.

In yet still other embodiments, the solar cell may further include: a reflection preventing layer between the substrate and the first electrode.

In yet still other embodiments, the solar cell may further include: a selective transmitting layer disposed between the first light absorption layer and the second light absorption layer. The selective transmitting layer may reflect visible light and transmit infrared rays.

In yet still other embodiments, the selective transmitting layer may include at least one of aluminum-titanium oxide, silicon-titanium oxide, aluminum-zirconium oxide, zirconium-titanium oxide, hafnium-titanium oxide, zirconium oxide, titanium oxide, hafnium oxide, aluminum oxide, silicon oxide, and silicon oxynitride.

In yet still other embodiments, the substrate may be an inorganic substrate formed of quartz and/or glass, or a transparent plastic substrate formed of polyethylene terephthalate (PET), polyethylene naphathalate (PEN), polycarbonate, polystyrene, and/or polypropylene.

### BRIEF DESCRIPTION OF THE DRAWINGS

The inventive concept will become more apparent in view of the attached drawings and accompanying detailed description.

FIG. 1 is a graph illustrating an interrelation between light energy and a light absorption rate according to change of contents of germanium and oxygen included in an amorphous silicon;

FIG. 2 is a cross-sectional view a solar cell having a tandem structure according to embodiments of the inventive concept;

FIG. 3A is a cross-sectional view of a first light absorption layer of a solar cell having a tandem structure according to embodiments of the inventive concept;

FIG. 3B is a graph illustrating oxygen-content ratios of semiconductor layers of a first light absorption layer according to some embodiments of the inventive concept;

FIG. 3C is a graph illustrating oxygen-content ratios of semiconductor layers of a first light absorption layer according to other embodiments of the inventive concept;

FIG. 4A is a cross-sectional view of a second light absorption layer of a solar cell having a tandem structure according to embodiments of the inventive concept;

FIG. 4B is a graph illustrating germanium-content ratios of semiconductor layers of a second light absorption layer according to some embodiments of the inventive concept; and

FIG. 4C is a graph illustrating germanium-content ratios of semiconductor layers of a second light absorption layer according to other embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

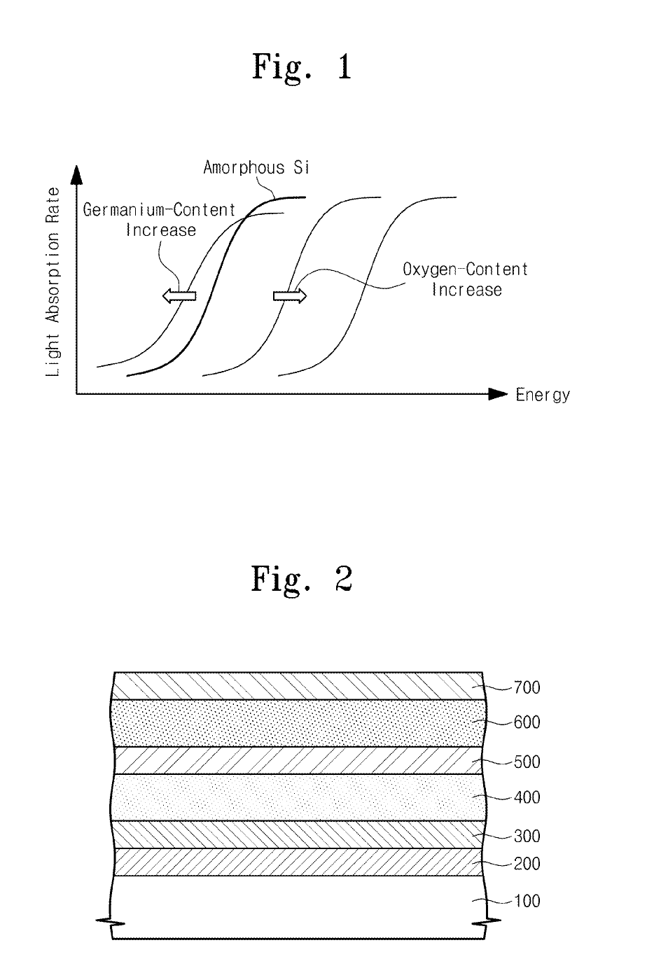

FIG. 1 is a graph illustrating an interrelation between light energy and a light absorption rate according to change of contents of germanium and oxygen included in an amorphous silicon. In detail, if the content of the oxygen increases, an energy band gap of the amorphous silicon may increase and a light absorption rate curve may be moved toward a short-wavelength. The amorphous silicon having high oxygen-content may absorb light of a relatively high energy. Alternatively, if the content of the germanium increases, the energy band gap of the amorphous silicon may be reduced and the light absorption rate curve may be moved toward a long-wavelength. The amorphous silicon having high germanium-content may absorb light of a relatively low energy.

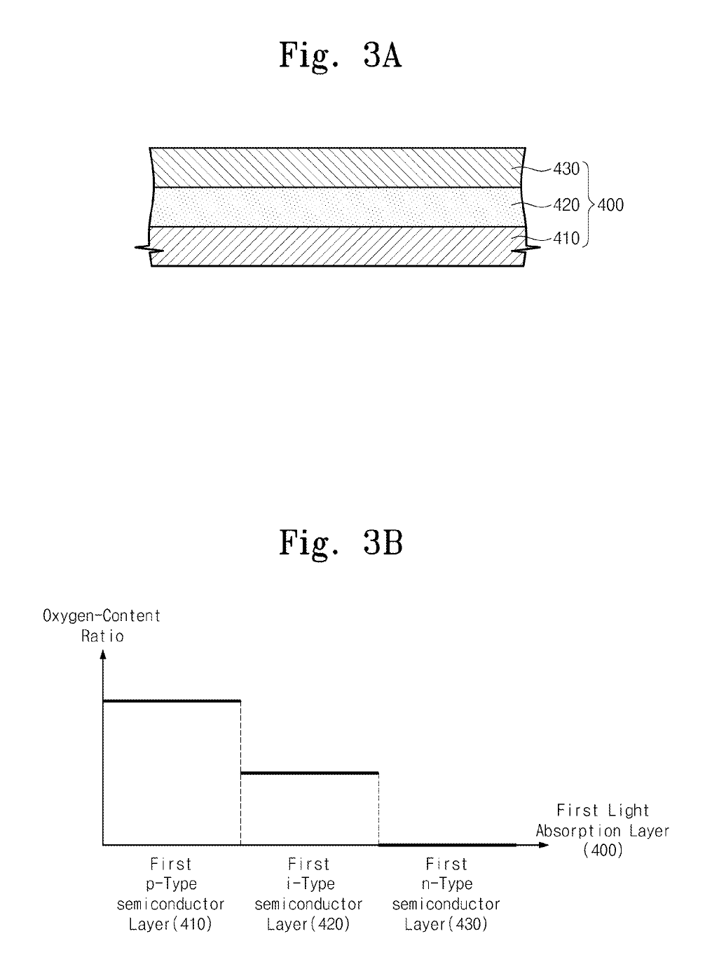

FIG. 2 is a cross-sectional view a solar cell having a tandem structure according to embodiments of the inventive concept.

Referring to FIG. 2, a reflection preventing layer 200, a first electrode 300, a first light absorption layer 400, a selective transmitting layer 500, a second absorption layer 600, and a second electrode 700 may be sequentially stacked on a substrate 100.

The substrate 100 may be transparent. For example, the substrate 100 may be an inorganic substrate formed of quartz and/or glass, or a transparent plastic substrate formed of polyethylene terephthalate (PET), polyethylene naphathalate (PEN), polycarbonate, polystyrene, and/or polypropylene.

The reflection preventing layer 200 may have a relatively great refractive index. For example, the reflection preventing layer 200 may be formed of silicon nitride (SiN).

The first electrode 300 may be transparent and have high electric conductivity. For example, the first electrode 300 may include indium tin oxide (ITO), stannum oxide (e.g., SnO₂), IrO₂, ZnO—(Ga₂O₃ or Al2O3), fluorine tin oxide (FTO), or any combination thereof. The first electrode 300 may have a resistivity within a range of about 10⁻¹¹ Ω-cm to about 10⁻² Ω-cm.

The first light absorption layer 400 may include a silicon layer including oxygen as an impurity, for example, a silicon oxide layer. The second light absorption layer 600 may include a silicon layer including germanium as an impurity, for example, a silicon-germanium layer. Visible light relatively corresponding to the short-wavelength may be absorbed in the first light absorption layer 400, and infrared rays relatively corresponding to the long-wavelength may be absorbed in the second light absorption layer 600. The first and second light absorption layers 400 and 600 may convert the light inputted from the outside of the solar cell into electric energy. Content ratios of the impurities may be controlled for controlling energy band gaps of the first and second light absorption layers 400 and 600

The first and second light absorption layers 400 and 600 may be deposited by a chemical vapor deposition (CVD) method and/or a sputtering method. When the silicon layer is deposited by the CVD method, a silicon source gas may be injected with an oxygen containing gas. For example, the oxygen containing gas may include at least one of O₂, N₂O, NO₂, and O₃. When the silicon layer is deposited by the sputtering method, oxygen may be used as a reaction gas or a silicon oxide target may be used. The silicon oxide layer has an energy band gap greater than that of a general silicon layer. The energy band gap of the silicon oxide layer may be controlled by controlling the content of the oxygen in the silicon oxide layer. The energy band gap of the silicon oxide layer may become increased from about 1.7 eV to about 2.5 eV or more by controlling the content of the oxygen in the silicon oxide layer.

An energy band gap of the silicon-germanium layer may be controlled by controlling a content of the germanium therein. The energy band gap of the silicon-germanium layer may become reduced from about 1.7 eV to about 1.3 eV or less by controlling the content of the germanium in the silicon-germanium layer. If a content ratio of the germanium exceeds 20% in the silicon-germanium layer, a photoelectric conversion effect may be reduced. This is because defects may occur at an interface by difference between lattice structures of silicon (Si) and silicon-germanium (SiGe) as the content ratio of the germanium becomes higher in the silicon-germanium layer. A lattice property of the silicon-germanium layer may be deteriorated by a high content ratio of the germanium therein and the defects of the interface may capture carries, such that photoelectric conversion efficiency may be reduced. Thus, it is preferable that the content ratio of the germanium in the silicon-germanium layer is limited to about 20% or less.

The selective transmitting layer 500 may reflect a light having a wavelength within a visible light wavelength band of about 400 nm to about 750 nm and transmit a light having a wavelength with an infrared rays wavelength band of about 750 nm to 1000 nm. The selective transmitting layer 500 may be disposed between the first light absorption layer 400 and the second absorption layer 600. The light may be scattered by the selective transmitting layer 500 to reduce light loss. The reflecting wavelength band and the transmitting wavelength band may be controlled by an optical thickness of the selective transmitting layer 500. The optical thickness may be represented as multiplication of a physical thickness and a refractive index of a medium. The refractive index of the medium may be changeable according to a composition ratio of materials constituting the medium. The selective transmitting layer 500 may include at least one of aluminum-titanium oxide, silicon-titanium oxide, aluminum-zirconium oxide, zirconium-titanium oxide, hafnium-titanium oxide, zirconium oxide, titanium oxide, hafnium oxide, aluminum oxide, silicon oxide, and silicon oxynitride.

The second electrode 700 may include a metal material having excellent electric conductivity for increasing collection efficiency of the electric power generated from the first and second light absorption layers 400 and 600.

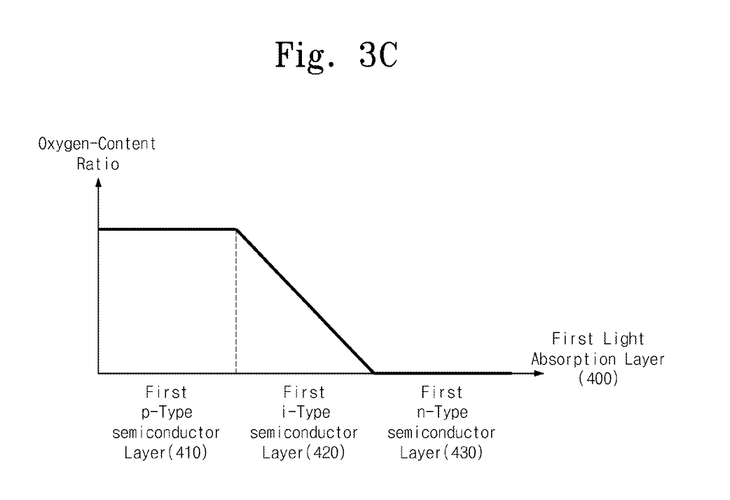

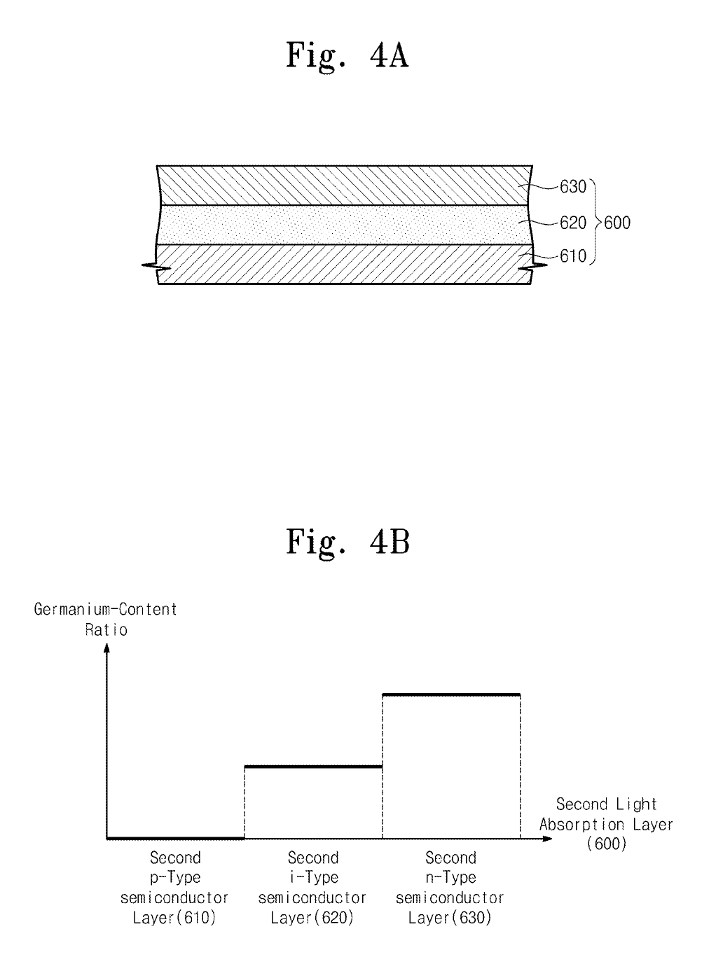

FIG. 3A is a cross-sectional view of a first light absorption layer of a solar cell having a tandem structure according to embodiments of the inventive concept.

Referring to FIG. 3A, the first light absorption layer 400 may include a first p-type semiconductor layer 410, a first i-type semiconductor layer 420, and a first n-type semiconductor layer 430.

FIG. 3B is a graph illustrating oxygen-content ratios of semiconductor layers of a first light absorption layer according to some embodiments of the inventive concept.

Referring to FIG. 3B, the first p-type semiconductor layer 410, the first i-type semiconductor layer 420, and the first n-type semiconductor layer 430 constituting the first light absorption layer 400 may have oxygen-content ratios different from each other, respectively. The first p-type semiconductor layer 410 and the first i-type semiconductor layer 420 may include silicon and oxygen, and the first n-type semiconductor layer 430 may include silicon. The first n-type semiconductor layer 430 may not include oxygen. The first p-type semiconductor layer 410 may be doped with III group element. For example, the III group element may include at least one of boron (B), aluminum (Al), gallium (Ga), and indium (In). The oxygen-content ratio of the first p-type semiconductor layer 410 may be higher than that of the first i-type semiconductor layer 420. Thus, the energy band gap of the first p-type semiconductor layer 410 may be the widest of the semiconductor layers 410, 420, and 430 of the first light absorption layer 400. The first i-type semiconductor layer 420 may correspond to an intrinsic semiconductor layer and absorb visible light. The first n-type semiconductor layer 430 may be doped with V group element. For example, the V group element may include at least one of nitrogen (N), phosphorus (P), arsenic (As), antimony (Sb), and bismuth (Bi). The oxygen-content ratio of the first n-type semiconductor layer 430 may be lower than that of the first i-type semiconductor layer 420. Thus, the energy band gap of the first n-type semiconductor layer 430 may be the narrowest of the semiconductor layers 410, 420, and 430 of the first light absorption layer 400.

FIG. 3C is a graph illustrating oxygen-content ratios of semiconductor layers of a first light absorption layer according to other embodiments of the inventive concept.

Referring to FIG. 3C, the first p-type semiconductor layer 410, the first i-type semiconductor layer 420, and the first n-type semiconductor layer 430 constituting the first light absorption layer 400 may have oxygen-content ratios different from each other, respectively. The oxygen-content ratio of the first i-type semiconductor layer 420 may be gradually changed. The oxygen-content ratio of the first i-type semiconductor layer 420 may be gradually reduced from the first p-type semiconductor layer 410 toward the first n-type semiconductor layer 430. The oxygen-content ratio of the first i-type semiconductor layer 420 may be reduced with a substantially regular gradient. The oxygen-content ratio may be about 0% in a portion of the first i-type semiconductor layer 420 adjacent to the first n-type semiconductor layer 430. The oxygen-content ratio of the first p-type semiconductor layer 410 may be the highest and the oxygen-content ratio of the first n-type semiconductor layer 430 may be the lowest in the semiconductor layers 410, 420, and 430 of the first light absorption layer 400.

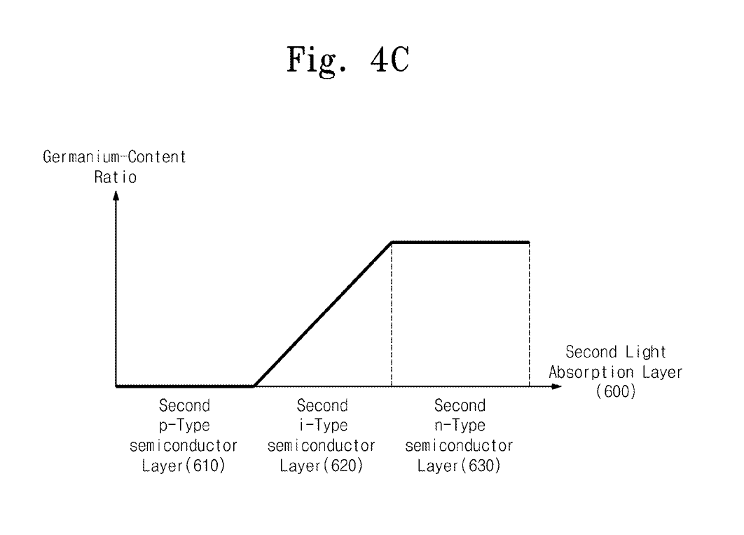

FIG. 4A is a cross-sectional view of a second light absorption layer of a solar cell having a tandem structure according to embodiments of the inventive concept.

Referring to FIG. 4A, the second light absorption layer 600 may include a second p-type semiconductor layer 610, a second i-type semiconductor layer 620, and a second n-type semiconductor layer 630.

FIG. 4B is a graph illustrating germanium-content ratios of semiconductor layers of a second light absorption layer according to some embodiments of the inventive concept.

Referring to FIG. 4B, the second p-type semiconductor layer 610, the second i-type semiconductor layer 620, and the second n-type semiconductor layer 630 constituting the second light absorption layer 600 may have germanium-content ratios different from each other, respectively. The second p-type semiconductor layer 610 may include silicon but may not include germanium. The second i-type semiconductor layer 620 and the second n-type semiconductor layer 630 may include silicon-germanium. The second p-type semiconductor layer 610 may be doped with III group element and have a germanium-content ratio lower than that of the second i-type semiconductor layer 620. Thus, the energy band gap of the second p-type semiconductor layer 610 may be the widest of the semiconductor layers 610, 620, and 630 of the second light absorption layer 600. The second i-type semiconductor layer 620 may correspond to an intrinsic semiconductor may absorb infrared rays. The second n-type semiconductor layer 630 may be doped with V group element and have a germanium-content ratio higher than that of the second i-type semiconductor layer 620. Thus, the energy band gap of the second n-type semiconductor layer 630 may be the narrowest of the semiconductor layers 610, 620, and 630 of the second light absorption layer 600.

FIG. 4C is a graph illustrating germanium-content ratios of semiconductor layers of a second light absorption layer according to other embodiments of the inventive concept.

Referring to FIG. 4C, the second p-type semiconductor layer 610, the second i-type semiconductor layer 620, and the second n-type semiconductor layer 630 constituting the second light absorption layer 600 may have germanium-content ratios different from each other, respectively. The germanium-content ratio of the silicon-germanium constituting the second i-type semiconductor layer 620 may be gradually changed. The germanium-content ratio of the second i-type semiconductor layer 620 may be gradually increased from the second p-type semiconductor layer 610 toward the second n-type semiconductor layer 630. The germanium-content ratio may be about 0% in a portion of the second i-type semiconductor layer 620 adjacent to the second p-type semiconductor layer 610. The germanium-content ratio of the second i-type semiconductor layer 620 may be increased with a substantially regular gradient. The germanium-content ratio may be about 20% in a portion of the second i-type semiconductor layer 620 adjacent to the second n-type semiconductor layer 630. The germanium-content ratio of the first p-type semiconductor layer 610 may be the lowest and the germanium-content ratio of the first n-type semiconductor layer 630 may be the highest in the semiconductor layers 610, 620, and 630 of the first light absorption layer 600.

In the other embodiments described with reference to FIGS. 3C and 4C, the i-type semiconductor layer between the p-type semiconductor layer and the n-type semiconductor layer may have the content ratio of an impurity (e.g., germanium or oxygen) which is gradually changed. Thus, the light absorption layer may be formed with homo-junction without hetero-junction. As a result, interface defects may be reduced, such that the light absorption efficiency of the solar cell may be improved.

According to embodiments of the inventive concept, it is possible to control the light absorption wavelength band of the solar cell by controlling the content ratio of the oxygen and/or germanium contained in the light absorption layer of the solar cell.

Additionally, the selective transmitting layer between the light absorption layers may reflect the visible light and selectively transmit infrared rays. Thus, the sunlight may be effectively scattered to improve the light absorption efficiency of the solar cell.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A solar cell comprising:
a substrate;
a first electrode on the substrate;
a first light absorption layer on the first electrode, the first light absorption layer including silicon containing oxygen;
a second light absorption layer on the first light absorption layer, the second light absorption layer including silicon containing germanium; and
a second electrode on the second light absorption layer,
wherein the first light absorption layer includes a plurality of semiconductor layers which have oxygen-content ratios different from each other, respectively; and
wherein the second light absorption layer includes a plurality of semiconductor layers which have germanium-content ratios different from each other, respectively.

2. The solar cell of claim 1, wherein the first light absorption layer comprises:
a first p-type semiconductor layer on the first electrode;
a first i-type semiconductor layer on the first p-type semiconductor layer, the first i-type semiconductor layer having an oxygen-content ratio lower than an oxygen-content ratio of the first p-type semiconductor layer; and
a first n-type semiconductor layer on the first i-type semiconductor layer, the first n-type semiconductor layer having an oxygen-content ratio lower than an oxygen-content ratio of the first i-type semiconductor layer.

3. The solar cell of claim 2, wherein the oxygen-content ratio of the first i-type semiconductor layer is gradually reduced from the first p-type semiconductor layer toward the first n-type semiconductor layer.

4. The solar cell of claim 2, wherein the second light absorption layer comprises:
a second p-type semiconductor layer on the first n-type semiconductor layer;
a second i-type semiconductor layer on the second p-type semiconductor layer, the second i-type semiconductor layer having a germanium-content ratio higher than a germanium-content ratio of the second p-type semiconductor layer; and
a second n-type semiconductor layer on the second i-type semiconductor layer, the second n-type semiconductor layer having a germanium-content ratio higher than a germanium-content ratio of the second i-type semiconductor layer.

5. The solar cell of claim 4, wherein the germanium-content ratio of the second i-type semiconductor layer is gradually increased from the second p-type semiconductor layer toward the second n-type semiconductor layer.

6. The solar cell of claim 5, wherein a maximum value of the germanium-content ratio of the second i-type semiconductor layer is about 20% or less.

7. The solar cell of claim 1, further comprising:
a reflection preventing layer between the substrate and the first electrode.

8. The solar cell of claim 1, further comprising:
a selective transmitting layer disposed between the first light absorption layer and the second light absorption layer,
wherein the selective transmitting layer reflects visible light and transmits infrared rays.

9. The solar cell of claim 8, wherein the selective transmitting layer includes at least one of aluminum-titanium oxide, silicon-titanium oxide, aluminum-zirconium oxide, zirconium-titanium oxide, hafnium-titanium oxide, zirconium oxide, titanium oxide, hafnium oxide, aluminum oxide, silicon oxide, and silicon oxynitride.

10. The solar cell of claim 1, wherein the substrate is an inorganic substrate formed of quartz and/or glass, or a transparent plastic substrate formed of polyethylene terephthalate (PET), polyethylene naphathalate (PEN), polycarbonate, polystyrene, and/or polypropylene.
